(19) United States
(12) Patent Application Publication
(10) Pub. No.: US 2009/0056807 A1
(43) Pub. Date: Mar. 5, 2009

(54) Solar cell and fabricating process thereof

(75) Inventors: Hsi-Chieh Chen, Hsinchu (TW); Chih-Hsun Chu, Hsinchu (TW)

Correspondence Address: BACON & THOMAS, PLLC, 625 SLATERS LANE, FOURTH FLOOR, ALEXANDRIA, VA, 22314-1176, US

(73) Assignee: MOSEL VITELIC INC., Hsinchu (TW)

(21) Appl. No.: 12/003,806

(22) Filed: Jan. 2, 2008

(30) Foreign Application Priority Data
Aug. 28, 2007 (TW) 096131912

(51) Int. Cl. H01L 31/028; H01L 31/04; H01L 21/00

(52) U.S. Cl. 136/261; 136/252; 438/98; 257/E21.001

(57) ABSTRACT

A solar cell includes a semiconductor substrate, an emitter layer, at least one emitter contact region and at least one first electrode. The emitter layer is formed on at least one surface of the semiconductor substrate. A p-n junction is formed between the emitter layer and the semiconductor substrate. The emitter contact region is formed on portions of the emitter layer and has the same type of dopant as the emitter layer. The emitter contact region has a higher dopant concentration than the emitter layer. The first electrode is coupled with the emitter contact region.

### FIELD OF THE INVENTION

The present invention relates to a photoelectric component and a fabricating process thereof, and more particularly to a solar cell and a fabricating process thereof.

### BACKGROUND OF THE INVENTION

Recently, the ecological problems resulted from fossil fuels such as petroleum and coal have been greatly aware all over the world. Consequently, there are growing demands on clean energy. Among various alternative energy sources, a solar cell is expected to replace fossil fuel as a new energy source because it provides clean energy without depletion and is easily handled. A solar cell is a device that converts light energy into electrical energy. The procedure of turning solar energy into electric energy is called the photovoltaic (PV) effect.

Hereinafter, a conventional process of fabricating a solar cell is illustrated as follows with reference to FIGS. 1(a)˜1(d).

First of all, as shown in FIG. 1(a), a p-type semiconductor substrate 11 is provided. Next, concave and convex patterns with a minute pyramidal shape called as a texture are formed on the surface of the semiconductor substrate 11 in order to improve light absorption and reduce light reflectivity. The texture structure is very minute and thus not shown in FIG. 1(a).

Next, as shown in FIG. 1(b), an n-type dopant source diffuses into the substrate at high temperature, thereby forming an n-type emitter layer 12 (also referred as a diffusion layer) on the light-receiving side S1 (or front side) and a p-n junction interface between the p-type semiconductor substrate 11 and the emitter layer 12. At this time, a phosphosilicate glass (PSG) layer 13 is formed on the emitter layer 12 by deposition.

Next, as shown in FIG. 1(c), the PSG layer 13 is removed to expose the emitter layer 12 by an etching procedure. Then, an anti-reflective coating (ARC) 14, which is made of for example silicon nitride (SiN), is formed on the emitter layer 12 in order to reduce light reflectivity and protect the emitter layer 12.

Next, as shown in FIG. 1(d), an aluminum conductor layer and a silver conductor layer are respectively formed on the back-lighted side S2 (or back side) and the light-receiving side S1 by screen printing. Afterwards, by firing the silver conductor layer, a first electrode 15 is formed on the light-receiving side S 1. Similarly, by firing the aluminum conductor layer, a back surface field (BSF) layer 16 and a second electrode 17 are formed on the back-lighted side S2, thereby completing the solar cell.

Although the solar cell produced by the above procedure has good PV effect, there are still some drawbacks. For example, since the emitter layer 12 is implanted with low n-type dopant concentration, the electric conductivity of the emitter layer 12 is usually undesirable. As a consequence, the contact resistance between the first electrode 15 and the emitter layer 12 is increased and the energy conversion efficiency of the overall solar cell is low. In case that the emitter layer 12 is implanted with high n-type dopant concentration, the electric conductivity of the emitter layer 12 is increased and the contact resistance between the first electrode 15 and the emitter layer 12 is lowered. Under this circumstance, however, the recombination rate of the electron-hole pairs at the surface of the solar cell is increased, and thus the blue light absorption of the solar cell and the energy conversion efficiency of the overall solar cell are insufficient.

In views of the above-described disadvantages resulted from the conventional method, the applicant keeps on carving unflaggingly to develop a solar cell and a fabricating process thereof according to the present invention through wholehearted experience and research.

### SUMMARY OF THE INVENTION

It is an object of the present invention to provide a solar cell and a fabricating procedure thereof in order to reduce the contact resistance between the first electrode and the emitter layer, reduce the recombination rate of the electron-hole pairs at the surface of the solar cell, increase the blue light absorption and enhance the energy conversion efficiency of the overall solar cell.

In accordance with an aspect of the present invention, there is provided a solar cell. The solar cell includes a semiconductor substrate, an emitter layer, at least one emitter contact region and at least one first electrode. The emitter layer is formed on at least one surface of the semiconductor substrate. A p-n junction is formed between the emitter layer and the semiconductor substrate. The emitter contact region is formed on portions of the emitter layer and has the same type of dopant as the emitter layer. The emitter contact region has a higher dopant concentration than the emitter layer. The first electrode is coupled with the emitter contact region.

In accordance with another aspect of the present invention, there is provided a process of fabricating a solar cell. The process includes steps of (a) providing a semiconductor substrate; (b) forming an emitter layer on at least one surface of the semiconductor substrate and forming a p-n junction between the emitter layer and the semiconductor substrate; (c) forming at least one emitter contact region on portions of the emitter layer, wherein the emitter contact region has the same type of dopant as the emitter layer and the emitter contact region has a higher dopant concentration than the emitter layer; and (d) forming at least one first electrode above the emitter layer and coupled with the emitter contact region.

The above contents of the present invention will become more readily apparent to those ordinarily skilled in the art after reviewing the following detailed description and accompanying drawings, in which:

### BRIEF DESCRIPTION OF THE DRAWINGS

FIGS. 1 (a)˜1(d) are schematic views illustration a process of fabricating a solar cell according to prior art;

FIGS. 2(a)˜2(f) are schematic views illustration a process of fabricating a solar cell according to a preferred embodiment of the present invention; and

FIG. 3 is a schematic top view partially illustrating the light-receiving side S1 of the solar cell.

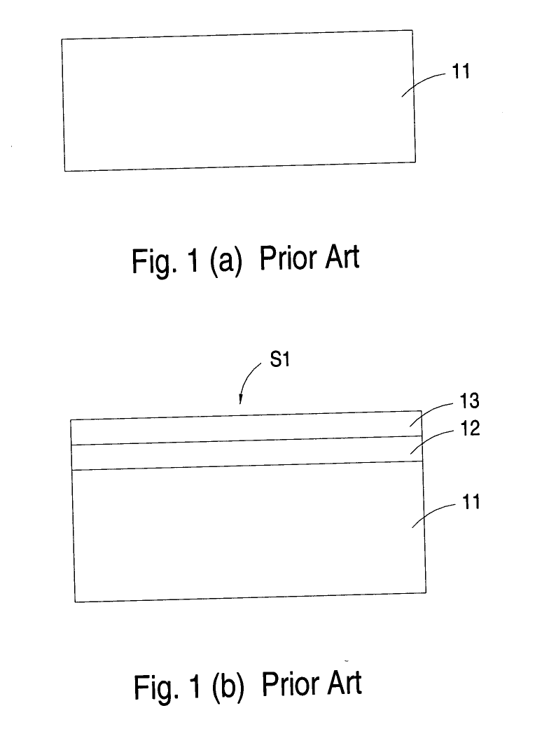

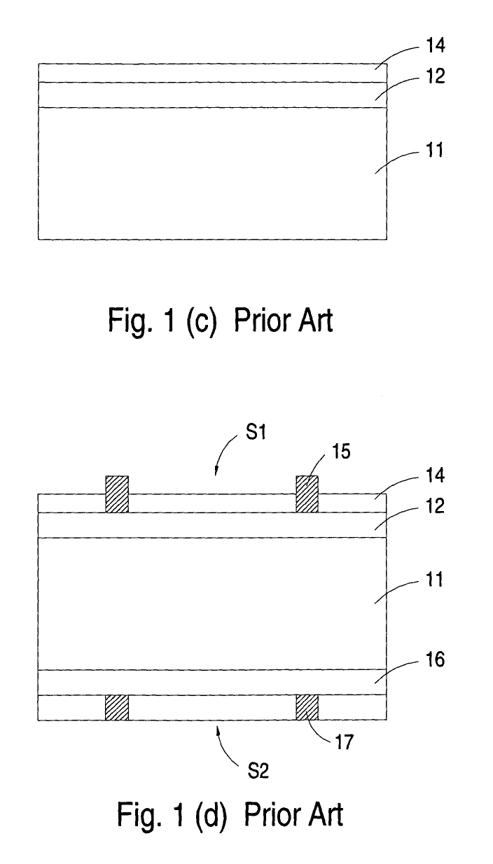

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

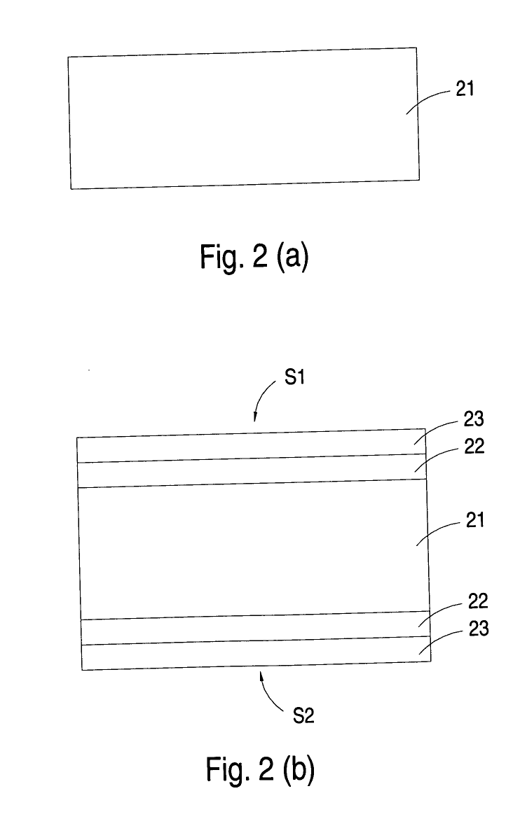

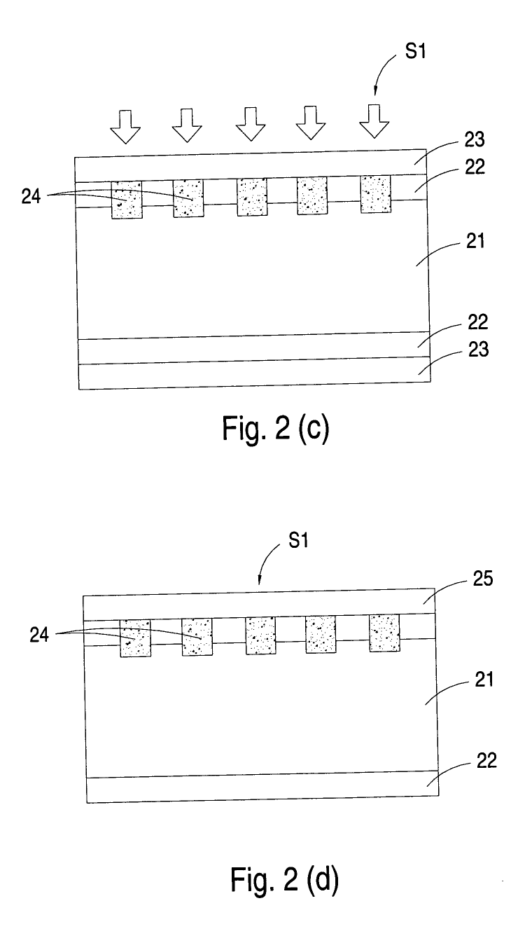

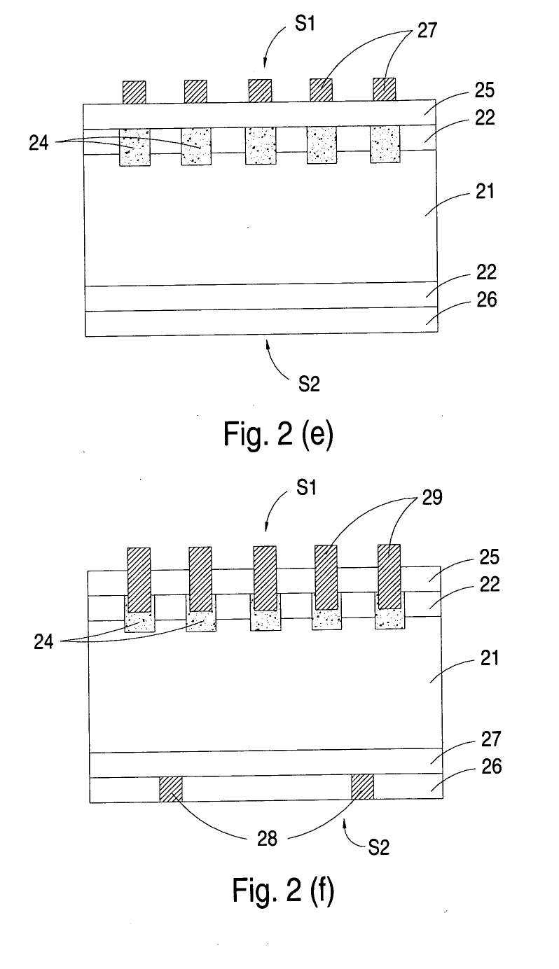

Hereinafter, a process of fabricating a solar cell according to a preferred embodiment of the present invention will be illustrated as follows with reference to FIGS. 2(a)˜2(f).

First of all, as shown in FIG. 2(a), a first semiconductor substrate 21 is provided. An example of the first semiconductor substrate 21 includes but is not limited to a p-type semiconductor substrate. Next, concave and convex patterns with a minute pyramidal shape called as a texture are formed on the surface of the first semiconductor substrate 21 in order to improve light absorption and reduce light reflectivity. The texture structure is very minute and thus not shown in FIG. 2(a). The texture structure of the first semiconductor substrate 21 is formed by for example a wet-etching procedure or a reactive ion etching procedure.

Next, as shown in FIG. 2(b), a dopant source (or referred as second type dopant) diffuses into the first semiconductor substrate 21 at high temperature, thereby forming low dopant concentration of second semiconductor substrates 22 on both of the light-receiving side S1 (or front side) and the back-lighted side S2 (or back side) as well as p-n junctions between the first semiconductor substrate 21 and respective second semiconductor substrates 22. The second semiconductor substrates 22 are also referred as emitter layers or diffusion layers. At this time, phosphosilicate glass (PSG) layers 23 are formed on the emitter layers 22. In this embodiment, the first semiconductor substrate 21 and the second semiconductor substrate 22 are different types of semiconductor substrates. For example, if the first semiconductor substrate 21 is a p-type silicon substrate, the second semiconductor substrate 22 is an n-type diffusion layer, and vice versa.

Next, as shown in FIG. 2(c), a plurality of emitter contact regions 24 are formed on the emitter layer 22 at the light-receiving side S1 by a laser-writing annealing procedure. More especially, the emitter contact regions 24 are implanted with the same type of dopant as the emitter layer 22 and the emitter contact region 24 has a higher dopant concentration than the emitter layer 22. In addition, the emitter contact regions 24 are partially extended to the first semiconductor substrate 21.

Next, as shown in FIG. 2(d), the PSG layer 23 is removed to expose the emitter layer 22 by an etching procedure. Then, an anti-reflective coating (ARC) 25 is formed on the emitter layer 22 at the light-receiving side S1 by for example chemical vapor deposition, thereby reducing light reflectivity and protecting the emitter layer 22. In an embodiment, the anti-reflective coating 25 is made of silicon nitride (SiN), silicon oxide, titanium dioxide, zinc oxide, tin oxide, magnesium dioxide, etc. In addition, the anti-reflective coating 25 may be formed by other procedure such as plasma chemical vapor deposition or vacuum evaporation.

Next, as shown in FIG. 2(e), a first conductor layer 26 and a second conductor layer 27 are successively formed on the back-lighted side S2 (or back side) and the light-receiving side S1 by screen printing. In this embodiment, the first conductor layer 26 is made of for example aluminum and the second conductor layer 27 is made of for example silver. During the second conductor layer 27 is formed on the anti-reflective coating 25, a predetermined electrode pattern may be aligned with the emitter contact regions 24 by using an alignment tool.

Next, as shown in FIG. 2(f), by firing the second conductor layer 27, first electrodes 29 are formed on the light-receiving side S1. The first electrodes 29 are extended to corresponding emitter contact regions 24 through the anti-reflective coating 25. Due to the heat transmitted from the first conductor layer 26, the emitter layer 22 at the back-lighted side S2 and a portion of the first semiconductor substrate 21 is changed to a back surface field (BSF) layer 27 and another portion of the first conductor layer 26 is changed to a second electrode 28, thereby completing the solar cell.

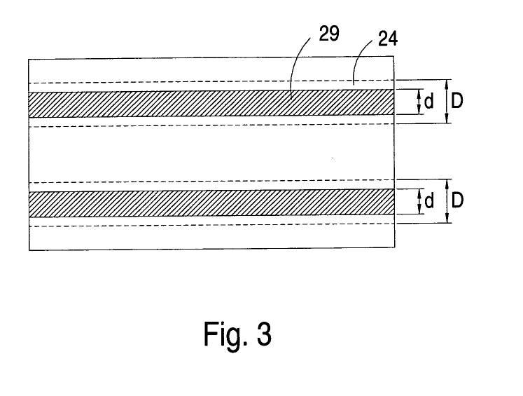

Please refer to FIG. 3, which is a schematic top view partially illustrating the light-receiving side S1 of the solar cell. As shown in FIG. 3, the first electrodes 29 (as indicated by the solid lines) are arranged above and substantially parallel with corresponding emitter contact regions 24 (as indicated by the dotted lines). The width D of the emitter contact region 24 is substantially greater than the width d of the first electrode 29. For example, the width D of the emitter contact region 24 is ranged from 150 to 200 μm and the width d of the first electrode 29 is approximately 105 μm. The emitter contact regions 24 are formed on portions of the emitter layer 22 by projecting a laser beam thereon. Then, the first electrodes 29 are formed above and coupled to the emitter contact regions 24. Since the width D of the emitter contact region 24 is substantially greater than the width d of the first electrode 29, the possibility of causing misalignment is minimized. In other words, during the second conductor layer 27 is formed on the anti-reflective coating 25 above the emitter contact regions 24 (as shown in FIG. 2(e)), the electrode pattern of the second conductor layer 27 will be precisely aligned with the emitter contact regions 24. As a consequence, the first electrodes 29 will be accurately connected to corresponding emitter contact regions 24 after the firing procedure.

Please refer to FIG. 2(f) again. Since the emitter contact regions 24 are formed on the emitter layer 22 by a laser-writing annealing procedure, the each of the emitter contact regions has a higher second-type dopant concentration than the emitter layer 22. Under this circumstance, the contact resistance between the first electrode 29 and the emitter layer 24 is reduced to for example 10 ohm/sq. Moreover, due to the relatively lower second-type dopant concentration of the emitter layer 22, the recombination rate of the electron-hole pairs at the surface of the solar cell is very low and the blue light absorption is increased. As a consequence, the energy conversion efficiency of the solar cell of the present invention is increased, for example, to about 20% more than the conventional solar cell.

From the above description, the solar cell provided by the present invention has reduced contact resistance and increased energy conversion efficiency in comparison with the conventional solar cell whose emitter layer is implanted with low-concentration dopant. Moreover, the problems of using high-concentration dopant (for example large recombination rate of the electron-hole pairs, low blue light absorption and low energy conversion efficiency) will be overcome when the solar cell of the present invention is utilized. In conclusion, the solar cell of the present invention has reduced contact resistance, reduced recombination rate of the electron-hole pairs, increased blue light absorption and enhanced energy conversion efficiency.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A solar cell comprising:
a semiconductor substrate;
an emitter layer formed on at least one surface of said semiconductor substrate, wherein a p-n junction is formed between said emitter layer and said semiconductor substrate;
at least one emitter contact region formed on portions of said emitter layer and has the same type of dopant as said emitter layer, wherein said emitter contact region has a higher dopant concentration than said emitter layer; and
at least one first electrode coupled with said emitter contact region.

2. The solar cell according to claim 1 further including at least one second electrode, which is coupled with said semiconductor substrate.

3. The solar cell according to claim 2 further including a back surface field layer, which is formed and interconnected between said semiconductor substrate and said second electrode.

4. The solar cell according to claim 1 further including an anti-reflective coating, which is formed between said first electrode and said emitter layer.

5. The solar cell according to claim 1 wherein said first electrode is made of silver and said second electrode is made of aluminum.

6. The solar cell according to claim 1 wherein said first semiconductor substrate is a first type of semiconductor substrate and said emitter layer is a second type of semiconductor diffusion layer.

7. The solar cell according to claim 6 wherein said first semiconductor substrate is a p-type silicon substrate and said emitter layer is an n-type diffusion layer.

8. The solar cell according to claim 1 wherein said emitter contact region is substantially parallel with said first electrode, and the width of said emitter contact region is substantially greater than that of said first electrode.

9. The solar cell according to claim 1 wherein said emitter contact region is implanted with the same type of dopant as said emitter layer and partially extended to said semiconductor substrate.

10. The solar cell according to claim 1 wherein said surface of said semiconductor substrate has a textured structure having concave and convex patterns formed thereon.

11. A process of fabricating a solar cell, comprising steps of:
(a) providing a semiconductor substrate;
(b) forming an emitter layer on at least one surface of said semiconductor substrate and forming a p-n junction between said emitter layer and said semiconductor substrate;
(c) forming at least one emitter contact region on portions of said emitter layer, wherein said emitter contact region has the same type of dopant as said emitter layer and said emitter contact region has a higher dopant concentration than said emitter layer; and
(d) forming at least one first electrode above said emitter layer and coupled with said emitter contact region.

12. The process according to claim 11 wherein said step (a) further includes a step of forming a textured structure having concave and convex patterns on said surface of said semiconductor substrate.

13. The process according to claim 11 wherein said step (c) includes sub-steps of:
(c1) forming at least one emitter contact region on portions of said emitter layer;
(c2) removing a phosphosilicate glass layer, which is formed on said emitter layer; and
(c2) forming an anti-reflective coating on said emitter layer.

14. The process according to claim 13 wherein said step (c1) is implemented by a laser-writing annealing procedure.

15. The process according to claim 13 wherein said step (d) includes sub-steps of:
(d1) forming a first conductor layer on a back-lighted side of said semiconductor substrate and a second conductor layer on said anti-reflective coating; and
(d2) firing said second conductor layer into said first electrode, forming a back surface field layer on said back-lighted side, and changing a portion of said first conductor layer into a second electrode.

16. The process according to claim 15 wherein said first electrode is made of silver and said second electrode is made of aluminum.

17. The process according to claim 11 wherein said first semiconductor substrate is a first type of semiconductor substrate and said emitter layer is a second type of semiconductor diffusion layer.

18. The process according to claim 17 wherein said first semiconductor substrate is a p-type silicon substrate and said emitter layer is an n-type diffusion layer.

19. The process according to claim 11 wherein said emitter contact region is substantially parallel with said first electrode, and the width of said emitter contact region is substantially greater than that of said first electrode.

20. The process according to claim 11 wherein said emitter contact region is implanted with the same type of dopant as said emitter layer and partially extended to said semiconductor substrate.
